(19) United States
(12) Patent Application Publication
(10) Pub. No.: US 2020/0370200 A1
(43) Pub. Date: Nov. 26, 2020

(54) METHOD OF MANUFACTURING ORIENTED STEEL PLATE

(71) Applicants: DENSO CORPORATION, Kariya-city (JP); THE UNIVERSITY OF TOKYO, Tokyo (JP)

(72) Inventors: Hiroki TAKAHASHI, Kariya-city (JP); Satoshi DOI, Kariya-city (JP); Keiichi OKAZAKI, Kariya-city (JP); Hidemasa OTSUBO, Kariya-city (JP); Yutaro SUGIMOTO, Kariya-city (JP); Jun YANAGIMOTO, Bunkyo-ku, Tokyo (JP)

(21) Appl. No.: 16/881,026

(22) Filed: May 22, 2020

(30) Foreign Application Priority Data
May 22, 2019 (JP) 2019-095983

(51) Int. Cl. C30B 1/06; H01F 1/16; H01F 41/00; C30B 1/12; C30B 29/52; C21D 9/46

(52) U.S. Cl. CPC C30B 1/06; H01F 1/16; H01F 41/00; H01F 1/147; C30B 29/52; C21D 9/46; C30B 1/12

(57) ABSTRACT

Provided is a method of manufacturing an oriented steel plate having two or more regions in each of which a crystal orientation is arranged in a specific direction. In the method, at least two single crystal steels are brought into contact with a principal surface of a polycrystalline steel plate so that crystal orientations of the single crystal steels and are arranged in different directions, and heat treatment of the single crystal steels and the polycrystalline steel plate is performed. This causes crystal growth following the crystal orientations of the single crystal steels to occur in the polycrystalline steel plate. Then, two or more single crystal steels having different crystal orientations are formed in the polycrystalline steel plate.

### CROSS-REFERENCE TO RELATED APPLICATION

This application is based on and claims the benefit of priority from earlier Japanese Patent Application No. 2019-095983 filed with the Japan Patent Office on May 22, 2019, the description of which is incorporated herein by reference.

### BACKGROUND

The present invention relates to a method of manufacturing an oriented steel plate.

Oriented steel plates having a single specific crystal orientation have been known. Oriented steel plates having a desired crystal orientation have good magnetic properties, and are thus used, for example, as electromagnetic steel plates. In this application, the oriented steel plates are referred to as oriented electromagnetic steel plates. Single crystal steels have a single crystal orientation. A technique is known in which a crystal orientation of a steel plate is arranged by secondary recrystallization phenomenon or the like.

### SUMMARY

An aspect of the present invention is a method of manufacturing an oriented steel plate, the method including: bringing at least two single crystal steels into contact with a polycrystalline steel plate (10) so that crystal orientations of the single crystal steels are arranged in different directions; and performing heat treatment of the single crystal steels and the polycrystalline steel plate.

### BRIEF DESCRIPTION OF THE DRAWINGS

In the accompanying drawings:

FIG. 1 is a schematic diagram showing a manufacturing process of an oriented steel plate according to a first embodiment.

FIG. 2 is a cross-sectional schematic diagram of a polycrystalline steel plate having a principal surface on which two single crystal steels are arranged according to the first embodiment.

FIG. 3 is a schematic diagram showing crystal orientations of the polycrystalline steel plate according to the first embodiment.

FIG. 4 is a schematic diagram showing crystal orientations of a first single crystal steel and a second single crystal steel according to the first embodiment.

FIG. 5 is a schematic diagram showing a cut portion after heat treatment according to the first embodiment.

FIG. 6 is a cross-sectional schematic diagram of an oriented steel plate according to the first embodiment.

FIG. 7 is a schematic diagram showing crystal orientations of oriented regions of the oriented steel plate according to the first embodiment.

FIG. 8 is a schematic diagram showing a particle size in oriented regions on a plane perpendicular to a rolling direction of the oriented steel plate according to the first embodiment.

FIG. 9 is a schematic diagram showing a particle size in oriented regions on a plane parallel to the rolling direction of the oriented steel plate according to the first embodiment.

FIG. 10 is a schematic diagram showing a polycrystalline steel plate having a principal surface on which three or more single crystal steels are arranged according to a first modification.

FIG. 11 is a schematic diagram showing a polycrystalline steel plate having an end portion at which two single crystal steels are arranged according to a second embodiment.

FIG. 12 is a cross-sectional schematic diagram of the polycrystalline steel plate showing a state in which heat treatment is performed while a temperature gradient is formed according to the second embodiment.

FIG. 13 is a schematic diagram showing a cut portion after the heat treatment according to the second embodiment.

FIG. 14 is a schematic diagram showing a polycrystalline steel plate having an end portion at which three or more single crystal steels are arranged according to a second modification.

FIG. 15 is a schematic diagram showing a manufacturing process of an oriented steel plate according to Experimental Example 1,

FIG. 16 is a schematic diagram showing a heating furnace according to Experimental Example 1.

FIG. 17 is an explanatory diagram showing an EBSD (electron backscatter diffraction) image, an EBSD image with a chroma of zero, and an angle map extracted from the EBSD image according to Experimental Example 1.

FIG. 18 is an explanatory diagram showing a simplified EBSD image according to Experimental Example 1.

FIG. 19 is an inverse pole figure of the EBSD image according to Experimental Example 1.

### DETAILED DESCRIPTION OF THE PREFERRED EMBODIMENTS

The inventor of the present disclosure has studied a method of manufacturing an oriented steel plate having two or more regions in each of which a crystal orientation is arranged in a specific direction based on following investigation.

Single crystal steels have a single crystal orientation, but due to their high manufacturing cost and long manufacturing time, the single crystal steels are not suitable for mass production. On the other hand, a technique is known in which a crystal orientation of a steel plate is arranged by secondary recrystallization phenomenon or the like. However, the technique requires a complicated manufacturing process, and causes poor orientation properties in a given crystal orientation such as {100} <001> orientation.

For example, in the application as an electromagnetic steel plate, it is desired to develop a steel plate having different crystal orientations, for example, two crystal orientations. According to the above method, however, two different crystal orientations cannot be formed unless two steel plates having different crystal orientations are joined together.

JP H2-263925 A discloses a method of manufacturing a bioriented electromagnetic steel plate. Specifically, JP H2-263925 A discloses a technique in which after hot rolling, a seed material for recrystallization is joined to a steel plate with a predetermined orientation relationship, and subsequently, the seed material and the steel plate are heated to a temperature that causes grain boundary migration to allow crystal growth following the orientation of the seed material to occur throughout the steel plate. JP H2-263925 A discloses that the manufacturing method can provide a bioriented electromagnetic steel plate having good magnetic properties.

JP H2-263925 A, the axis of easy magnetization is in two directions, but the crystal orientation is in a single direction. Thus, the technique described in JP H2-263925 A cannot form two or more crystal orientations.

The present invention has been made in view of such a problem, and has an object of providing a method of manufacturing an oriented steel plate having two or more regions in each of which a crystal orientation is arranged in a specific direction.

An aspect of the present invention is a method of manufacturing an oriented steel plate (1), the method including: bringing at least two single crystal steels (2) into contact with a principal surface (101) of a polycrystalline steel plate (10) so that crystal orientations of the single crystal steels are arranged in different directions; and performing heat treatment of the single crystal steels and the polycrystalline steel plate, thereby causing crystal growth following the crystal orientations of the single crystal steels to occur in the polycrystalline steel plate to form two or more single crystal steels having different crystal orientations in the polycrystalline steel plate.

In the manufacturing method, at least two single crystal steels are brought into contact with a principal surface of a polycrystalline steel plate so that crystal orientations of the single crystal steels are arranged in different directions, and heat treatment of the single crystal steels and the polycrystalline steel plate is performed. This causes crystal growth following the crystal orientations of the single crystal steels to occur in the polycrystalline steel plate to form two or more single crystal steels having different crystal orientations in the polycrystalline steel plate. As a result, it is possible to obtain an oriented steel plate having two or more regions in each of which a crystal orientation is arranged in a specific direction.

As described above, the aspect can provide a method of manufacturing an oriented steel plate having two or more regions in each of which a crystal orientation is arranged in a specific direction.

### First Embodiment

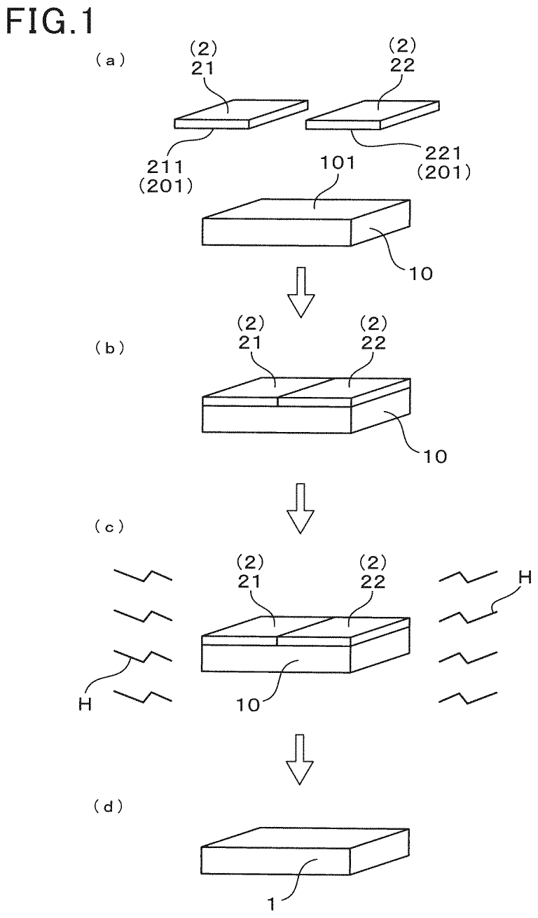

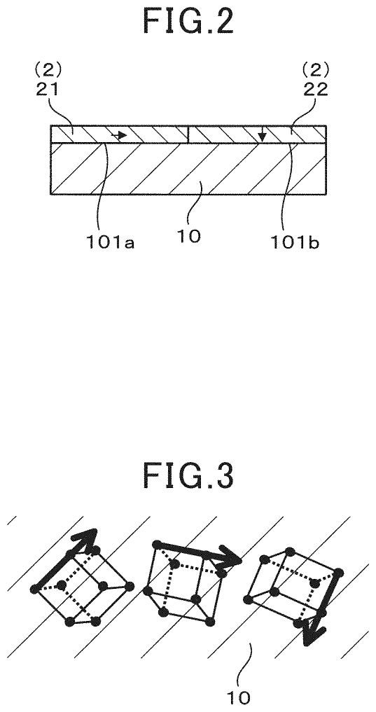

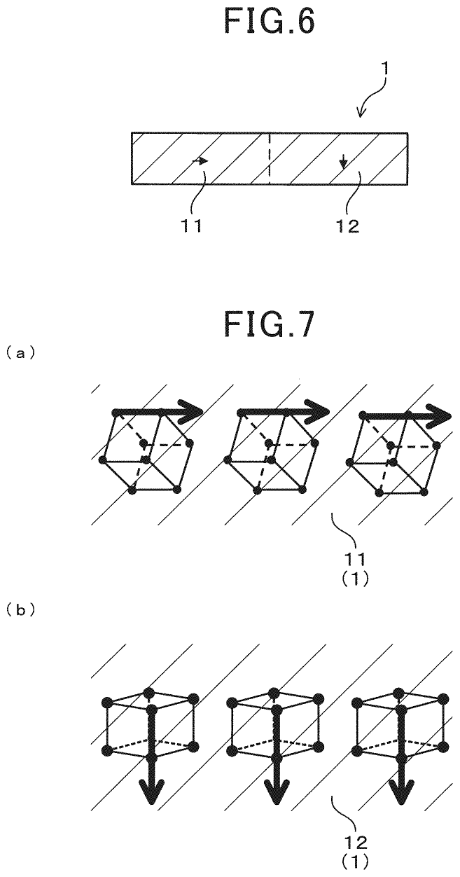

A first embodiment regarding a method of manufacturing an oriented steel plate 1 will be described with reference to FIGS. 1 to 9. As shown in FIGS. 6 and 7, the oriented steel plate 1 has two or more oriented regions each of which has a specific crystal orientation, and can be referred to as a multi-oriented steel plate. In FIGS. 2 to 7, arrows shown in a single crystal steel 2, a polycrystalline steel plate 10, and the oriented steel plate 1 indicate a specific direction of a crystal orientation.

As shown in FIG. 1, the oriented steel plate 1 is manufactured by bringing at least two single crystal steels 21 and 22 into contact with a principal surface 101 of the polycrystalline steel plate 10, and performing heat treatment of the polycrystalline steel plate 10 and the single crystal steels 21 and 22. The single crystal steels 21 and 22 are used as a core for a crystal orientation, i.e., a core material, and can be removed after the heat treatment. The first embodiment will be described in detail below.

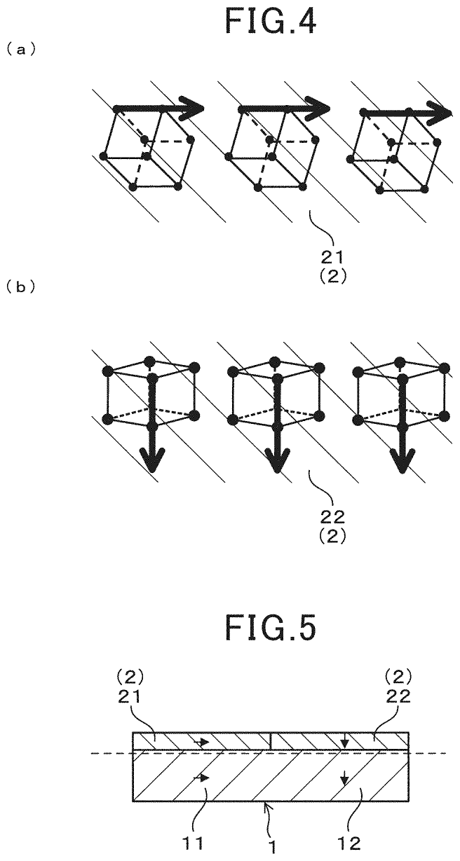

As shown in FIGS. 1 (a) and 4, first, the at least two single crystal steels 21 and 22 having different crystal orientations are prepared. The single crystal steels 21 and 22 have abutment surfaces 211 and 221 which are brought into contact with the polycrystalline steel plate 10. The single crystal steels 21 and 22 are manufactured, for example, by being cut out from a single crystal steel having a predetermined crystal orientation. At this time, the single crystal steels 21 and 22 can be cut out so that the abutment surfaces 211 and 221 have a desired crystal orientation. Thus, the single crystal steels 21 and 22 having various crystal orientations can be obtained.

The polycrystalline steel plate 10 is manufactured, for example, by performing hot rolling of a steel slab, and if necessary, by performing cold rolling, annealing, and the like. Examples of the steel include ferritic stainless steel, austenitic stainless steel, carbon steel, and electromagnetic steel. Examples of a crystal structure of the steel include cubic crystals such as a body-centered cubic crystal and a face-centered cubic crystal. As shown in FIG. 3, the polycrystalline steel plate 10 is composed of many crystal grains having different crystal orientations and is a non-oriented steel plate.

Next, as shown in FIGS. 1 (b) and 2, the single crystal steels 21 and 22 are brought into contact with the principal surface 101 of the polycrystalline steel plate 10. FIGS. 1 to 7 show an example in which two single crystal steels, i.e., the first single crystal steel 21 and the second single crystal steel 22 are used, but two or more single crystal steels 2 may be used. Herein, single crystal steels are given an ordinal number, for example, as in the first single crystal steel 21 and the second single crystal steel 22.

On the principal surface 101 of the polycrystalline steel plate 10, the first single crystal steel 21 and the second single crystal steel 22 are arranged so that the crystal orientations of the first single crystal steel 21 and the second single crystal steel 22 are arranged in different directions. FIG. 2 and FIGS. 4 (a) and (b) show the crystal orientations of the first single crystal steel 21 and the second single crystal steel 22 when the first single crystal steel 21 and the second single crystal steel 22 are arranged on the principal surface 101 of the polycrystalline steel plate 10. The direction and arrangement of the crystal orientations of the single crystal steels can be changed, and by changing the direction and arrangement of the crystal orientations, after the heat treatment, a region in which a crystal orientation is arranged in a specific direction can be formed in various patterns. Hereinafter, the region in the oriented steel plate 1 in which a crystal orientation is arranged in a specific direction is referred to as an “oriented region”. Each oriented region is composed of a single crystal grown in the polycrystalline steel plate 10.

The crystal orientations of the single crystal steels 2 are not particularly limited, and the single crystal steels 2 having the same crystal orientation may be brought into contact with the principal surface 101 of the polycrystalline steel plate 10 so that the crystal orientations of the single crystal steels 2 are arranged in different directions. Alternatively, the single crystal steels 2 having different crystal orientations may be brought into contact with the principal surface 101 of the polycrystalline steel plate 10.

The single crystal steels 2 may have a desired crystal orientation. Specific examples of the crystal orientation include {100} <001>, {123} <634>, {011} <211>, {112} <111>, {110} <001>, and the like.

The single crystal steels 2 are preferably in surface contact with the polycrystalline steel plate 10. In this case, during heating, crystal growth following the crystal orientations of the single crystal steels 2 is more likely to occur in the polycrystalline steel plate 10. As a result, the oriented regions can be increased in the oriented steel plate 1.

A shape of the single crystal steels 2 is not particularly limited, but is preferably, for example, a plate shape. In this case, by bringing principal surfaces (i.e., abutment surfaces 201) of the plate-shaped single crystal steels 2 into contact with the principal surface 101 of the polycrystalline steel plate 10, the single crystal steels 2 can be easily in surface contact with the principal surface 101 of the polycrystalline steel plate 10. Furthermore, a larger contact area provides a larger growth surface. As a result, the orientation properties are further improved.

A thickness of the single crystal steels 2 is not particularly limited, but when the single crystal steels 2 have a plate shape, the single crystal steels 2 have a thickness, for example, in the range of 0.1 to 1.0 mm. A thickness of the polycrystalline steel plate 10 is not particularly limited either. However, from the viewpoint that productivity of the manufacture of a oriented steel plate is improved when crystal growth proceeds in the entire polycrystalline steel plate 10 in the thickness direction in a short period of time, the thickness of the polycrystalline steel plate 10 is preferably 0.8 mm or less, more preferably 0.5 mm or less, and still more preferably 0.35 mm or less. From the viewpoint of manufacturing cost of a polycrystalline steel plate and the like, the thickness of the polycrystalline steel plate 10 is preferably 0.1 mm or more.

A crystal grain size of the polycrystalline steel plate 10 is, for example, in the range of 20 to 100 μm. The crystal grain size of the polycrystalline steel plate 10 is the crystal grain size of the polycrystalline steel plate 10 before being subjected to heat treatment and the crystal grain size of the polycrystalline steel plate 10 before being provided with distortion (described later). The crystal grain size is measured, for example, by the average number of crystal grains per unit area measured by using a microscope. Specifically, the crystal grain size is measured in accordance with JIS G 0551 “Steels-Micrographic determination of the apparent grain size”.

A contact surface between the single crystal steels and the polycrystalline steel plate may be etched. In this case, a crystal grain boundary is exposed, leading to improvement in degree of adhesion of a joining surface and promotion of crystal growth. The etching may be performed by using hydrochloric acid, nitric acid alcohol solution, oxalic acid, or the like.

After the single crystal steels 2 are brought into contact with the polycrystalline steel plate 10, heat treatment is performed. Thus, the single crystal steels 2 and the polycrystalline steel plate 10 are heated. The heating may be performed, for example, in a heating furnace. By the heating, crystal orientations of the crystal grains constituting the polycrystalline steel plate 10 are arranged following the crystal orientations of the single crystal steels 2, and crystal growth occurs in the polycrystalline steel plate 10. The single crystal steels 2 serve as a core for the crystal orientation, and thus can be referred to as a core material. The polycrystalline steel plate 10 is a material in which a crystal orientation is arranged following a crystal orientation of the core material, and thus can be referred to as a blank plate.

As shown in FIGS. 2 to 7, crystal growth that occurs when the first single crystal steel 21 and the second single crystal steel 22 are used will be described. As shown in FIGS. 2 and 5, by performing heat treatment, from a contact surface 101a between the first single crystal steel 21 and the polycrystalline steel plate 10 toward the polycrystalline steel plate 10, a polycrystalline steel is oriented following the crystal orientation of the first single crystal steel 21, and further, crystal grains constituting the polycrystalline steel are grown. Similarly, from a contact surface 101b between the second single crystal steel 22 and the polycrystalline steel plate 10 toward the polycrystalline steel plate 10, a polycrystalline steel is oriented following the crystal orientation of the second single crystal steel 22, and further, crystal grains constituting the polycrystalline steel are grown. Thus, while the single crystal steels 2 serve as a core material for the crystal orientation and the polycrystalline steel plate 10 serves as a blank plate, crystal growth occurs from the core material toward the blank plate, and crystal grains of a polycrystal constituting the polycrystalline steel plate 10 are oriented and grown. As a result, in the polycrystalline steel plate 10, for example, oriented regions 11 and 12 in two orientations are formed. The oriented regions 11 and 12 each have a predetermined crystal orientation.

The heating is performed, for example, in a heating furnace. As shown in FIG. 1, when the single crystal steels 2 are arranged to overlap the entire principal surface 101 of the polycrystalline steel plate 10, the arrangement of the crystal orientation can proceed, for example, by uniform heating. The uniform heating is a method of uniformly heating the entire polycrystalline steel plate 10 with which the single crystal steels 2 are in contact. From the viewpoint of preventing oxidation of the polycrystalline steel plate 10, the heating is preferably performed in a non-oxidizing gas atmosphere or under vacuum. As shown in a second embodiment, the single crystal steels 2 may be arranged on a part of the principal surface 101 of the polycrystalline steel plate 10.

A heating temperature of the heat treatment is preferably a recrystallization temperature or more and a melting point or less of the polycrystalline steel plate 10. Specifically, the heating temperature may be adjusted, for example, to the range of 500° C. or more and 1500° C. or less. From the viewpoint of promoting the growth of the grains, the heating temperature is preferably 850° C. or more, and more preferably 1000° C. or more.

At the above target heating temperature, time of the heat treatment is, for example, in the range of 30 minutes or more and 4 hours or less, and preferably in the range of 2 hours or more and 4 hours or less.

The heat treatment is preferably performed while pressure is applied to the single crystal steels 2 and the polycrystalline steel plate 10 in a contact direction of the single crystal steels 2 and the polycrystalline steel plate 10. In this case, due to an increase in contact area, crystal growth is promoted. A load when pressure is applied to the single crystal steels 2 and the polycrystalline steel plate 10 is preferably in the range of 400 to 1000 N. In this case, the single crystal steels 2 can be sufficiently in contact with the polycrystalline steel plate 10 to such an extent that the single crystal steels 2 and the polycrystalline steel plate 10 are not provided with distortion. Specifically, the heat treatment while pressure is applied to the single crystal steels 2 and the polycrystalline steel plate 10 may be performed by hot pressing.

After the heat treatment, the polycrystalline steel plate 10 may be cooled, for example, by air cooling, nitrogen gas cooling, natural cooling, or the like. Furthermore, a speed of the cooling of the polycrystalline steel plate 10 after the heat treatment is not particularly limited, but is, for example, in the range of −5° C./second or more and −1° C./second or less, and preferably in the range of −3° C./second or more and −1° C./second or less.

Before the heat treatment, the polycrystalline steel plate 10 is preferably provided with distortion. In this case, during the heat treatment, recrystallization occurs and the arrangement of the crystal orientation is further promoted. The distortion is, for example, compression distortion. The polycrystalline steel plate 10 may be provided with compression distortion in the thickness direction of the polycrystalline steel plate 10 before the single crystal steels 2 are brought into contact with the polycrystalline steel plate 10.

The polycrystalline steel plate 10 is provided with compression distortion by being subjected to rolling, shot blasting, uniaxial compression, or the like. The polycrystalline steel plate 10 is preferably subjected to rolling. In this case, the entire polycrystalline steel plate 10 in the thickness direction can be continuously provided with distortion, and thus productivity is improved. When the rolling is performed, a rolling reduction ratio is preferably in the range of 5 to 75%. By setting the rolling reduction ratio to 5% or more, during the heat treatment, recrystallization occurs and the arrangement of the crystal orientation is further promoted. In order to further improve the promotion effect, the rolling reduction ratio is more preferably 10% or more, and still more preferably 25% or more. Furthermore, by setting the rolling reduction ratio to 75% or less, processability of the rolling is not reduced and productivity can be maintained. From the viewpoint of further improving the effect of maintaining productivity, the rolling reduction ratio is more preferably 60% or less, and still more preferably 50% or less.

After the heat treatment, the single crystal steels 2 can be removed. In the present embodiment, as shown in FIG. 1, since the heat treatment is performed while the single crystal steels 2 are arranged to overlap the entire surface of the polycrystalline steel plate 10, after the heat treatment, the single crystal steels 2 cover the entire surface of the oriented steel plate 1. The single crystal steels 2 after the heat treatment are joined to the oriented steel plate 1, and thus the single crystal steels 2 can be removed by being cut. For example, the single crystal steels 2 can be removed by being cut in a surface direction, for example, at a position slightly shifted from the joining surface of the single crystal steels 2 and the oriented steel plate 1 toward the oriented steel plate 1, as a cutting position indicated by a dashed line in FIG. 5. The single crystal steels 2 may be removed before, during, or after the cooling. However, from the viewpoint of workability, the single crystal steels 2 are preferably removed after the cooling.

Thus, as shown in FIGS. 5 to 7, the oriented steel plate 1 having the two oriented regions 11 and 12 having different crystal orientations can be obtained. By using three or more single crystal steels, oriented regions having three or more orientations can be formed in the polycrystalline steel plate 10. The crystal orientation of the oriented steel plate 1 is measured, for example, by an electron back-scattering diffraction method. The electron back-scattering diffraction method is referred to as an EBSD method. The EBSD method provides an EBSD map of crystal orientations. In the EBSD map, differences in crystal orientation are typically indicated by differences in color. The EBSD map can also show crystal orientations as an inverse pole figure.

As shown in FIGS. 6 and 7, the oriented steel plate 1 has the two or more oriented regions 11 and 12, and at a boundary between the oriented regions 11 and 12, in some cases, a region is formed in which the crystal orientations of the oriented regions 11 and 12 interfere with each other. The region tends to include one or more crystal grains having a crystal orientation different from the crystal orientations of the oriented regions 11 and 12 and having a particle size smaller than a particle size of the crystal grains in the oriented regions 11 and 12.

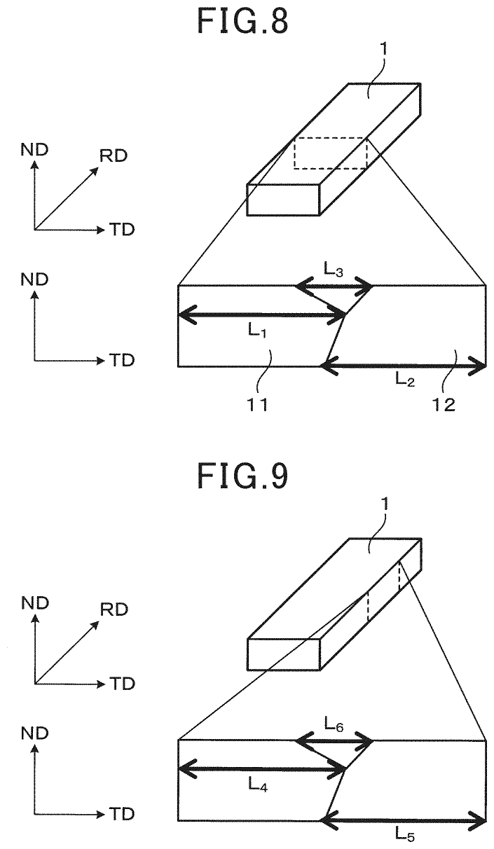

The oriented regions 11 and 12 of the oriented steel plate 1 are each composed of a crystal grain having a single crystal orientation. As shown in FIGS. 8 and 9, in the oriented regions 11 and 12, an index is an identical (i.e., an orientation difference of 15° or less) crystal grain having a particle size of 1.5 mm or more. The orientation difference of 15° or less is a typical angle of a low-angle grain boundary. The orientation difference and the particle size can be measured by using an EBSD image. The oriented steel plate 1 preferably has two or more crystal grains of a single crystal that have different crystal orientations and have a particle size of 1.5 mm or more. The crystal grains having different crystal orientations are, for example, adjacent to each other.

As shown in FIGS. 8 and 9, the particle size (of the crystal grains of the single crystal) in the oriented regions 11 and 12 is the particle size when a plane perpendicular to or parallel to a rolling direction RD of the oriented steel plate 1 is observed. The plane perpendicular to the rolling direction RD is a plane formed by a thickness direction ND and a direction TD (i.e., transverse direction) perpendicular to the rolling direction RD. Furthermore, the plane parallel to the rolling direction RD is a plane formed by the thickness direction ND and the rolling direction RD. On at least one of the two planes, the oriented steel plate 1 preferably has oriented regions in which a crystal grain has a particle size of 1.5 mm or more as described above. In this case, the oriented regions 11 and 12 can sufficiently exert physical properties based on the respective crystal orientations. Thus, in this case, the oriented steel plate 1 is suitable to be used, for example, as an electromagnetic steel plate or the like. In the application as an electromagnetic steel plate, the oriented steel plate 1 can be referred to as an oriented electromagnetic steel plate, and since the oriented steel plate 1 has two or more orientations, the oriented steel plate 1 can be referred to as a multi-oriented electromagnetic steel plate.

FIG. 8 shows an example of a crystal structure of the oriented steel plate 1 on the plane perpendicular to the rolling direction RD, and FIG. 9 shows an example of a crystal structure of the oriented steel plate 1 on the plane parallel to the rolling direction RD. As shown in FIG. 8, a particle size of the crystal grains on the plane perpendicular to the rolling direction RD is a maximum width of the crystal grains in the transverse direction TD. In FIG. 8, the maximum widths of the crystal grains are represented by L₁ to L₃. As shown in FIG. 9, a particle size of the crystal grains on the plane parallel to the rolling direction RD is a maximum width of the crystal grains in the rolling direction RD. In FIG. 9, the maximum widths of the crystal grains are represented by L₄ to L₆.

The rolling direction RD can be determined, for example, by observing a crystalline structure. In a rolled plate, a crystalline structure is, for example, a fibrous structure, and a longitudinal direction of crystal grains constituting the crystalline structure is the rolling direction RD. The crystalline structure can be examined, for example, by observation using a scanning electron microscope or by the EBSD method.

As described above, the manufacturing method of the present embodiment can manufacture the oriented steel plate 1 having the two or more oriented regions 11 and 12 each of which has a specific crystal orientation. At the boundary between the oriented regions 11 and 12, the oriented steel plate 1 substantially has no gap, no joining portion, or no joining surface. Thus, there is almost no difference in surface roughness of the oriented steel plate 1 between the boundary of the oriented regions 11 and 12 and a portion around the boundary. Specifically, the difference in the surface roughness between the boundary of the oriented regions 11 and 12 and the portion around the boundary is preferably 3.2 μm or less. The oriented regions 11 and 12 are flush with each other. The surface roughness is measured by using a laser microscope. The oriented steel plate 1 is, for example, composed of a single plate.

The oriented regions 11 and 12 of the oriented steel plate 1 exhibit predetermined physical properties on the basis of the respective crystal orientations. For example, while the oriented steel plate 1 is a single plate, the oriented regions 11 and 12 can exhibit different physical properties. Examples of the physical properties include magnetic properties, an r-value, cutting resistance, and corrosion resistance.

(First Modification)

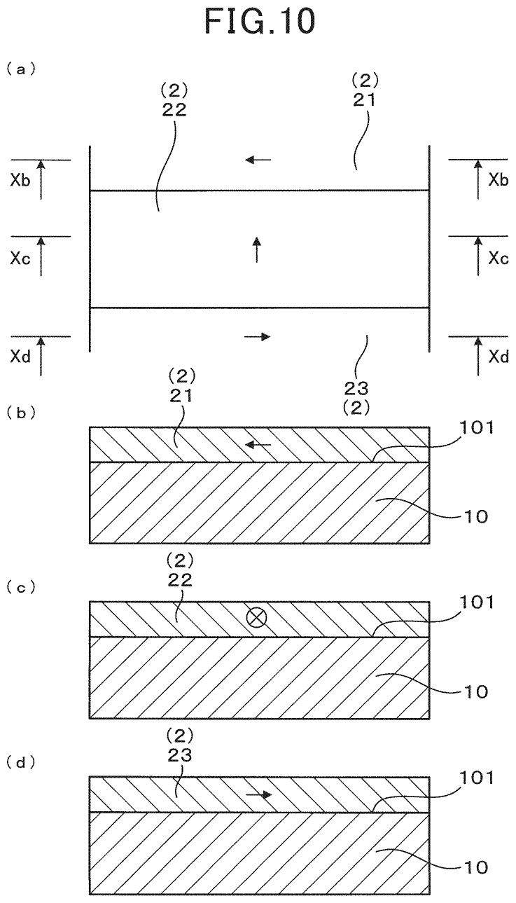

A first modification is an example in which three or more single crystal steels 2 are used to manufacture the oriented steel plate 1. Among reference signs used in the first modification and subsequent embodiments, the same reference signs as those used in the previously described embodiments indicate the same components or the like as those of the previously described embodiments unless otherwise specified. In the drawings referred to in the first modification and subsequent embodiments, arrows shown in the single crystal steel 2, the polycrystalline steel plate 10, and the oriented steel plate 1 indicate a direction of the crystal orientation, and a circled X shown in FIG. 10 (b) indicates a direction of the crystal orientation from a front side (in other words, a closer side) toward a back side (in other words, a farther side) of the page.

As shown in FIGS. 10 (a) to (d three or more single crystal steels 21, 22, and 23 are arranged in contact with the principal surface 101 of the polycrystalline steel plate 10. In the first modification, as in the first embodiment, the single crystal steels 2 are arranged to be in contact with the entire principal surface 101 of the polycrystalline steel plate 10.

FIGS. 10 (a) to (d) show a region in which the three single crystal steels 2, which are the first single crystal steel 21, the second single crystal steel 22, and the third single crystal steel 23, are arranged on the principal surface 101 of the polycrystalline steel plate 10, but three or more single crystal steels 2 may be arranged on the polycrystalline steel plate 10. Except for this point, the oriented steel plate 1 can be manufactured in the same manner as the first embodiment. Specifically, by performing heat treatment in the same manner as the first embodiment, crystal growth following crystal orientations of the single crystal steels 21, 22, and 23 proceeds in the polycrystalline steel plate 10. This makes it possible to obtain the oriented steel plate 1 having, for example, three or more oriented regions each of which has a desired crystal orientation.

### Second Embodiment

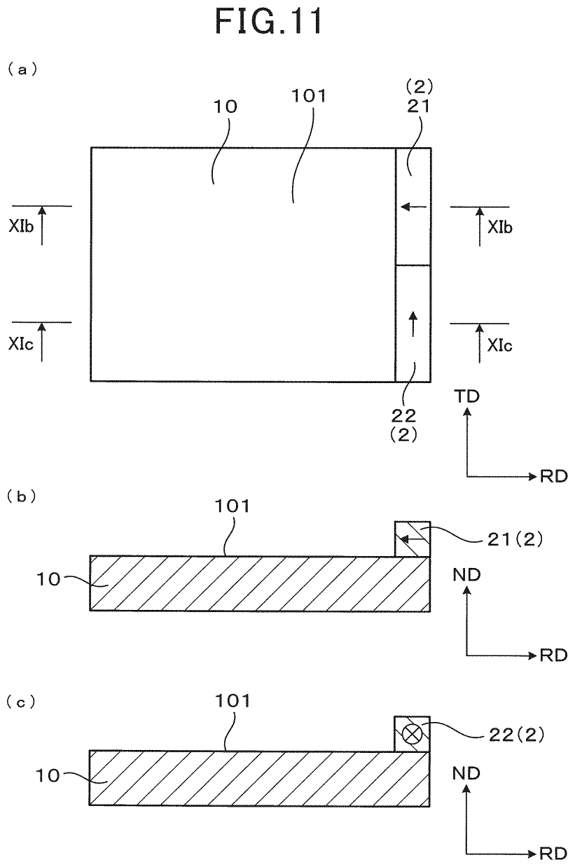

Next, the second embodiment will be described. In the second embodiment, the single crystal steels 2 are brought into contact with an end portion of the principal surface 101 in a direction perpendicular to the thickness direction ND of the polycrystalline steel plate 10 and crystal growth is caused. As shown in FIG. 11 (a) to (c), the single crystal steels 2 are arranged in contact with an end portion of the polycrystalline steel plate 10, for example, in the rolling direction RD. The single crystal steels 2 are arranged, for example, in series on the principal surface 101 of the polycrystalline steel plate 10. In the present embodiment, as the single crystal steels 2, the first single crystal steel 21 and the second single crystal steel 22 are arranged.

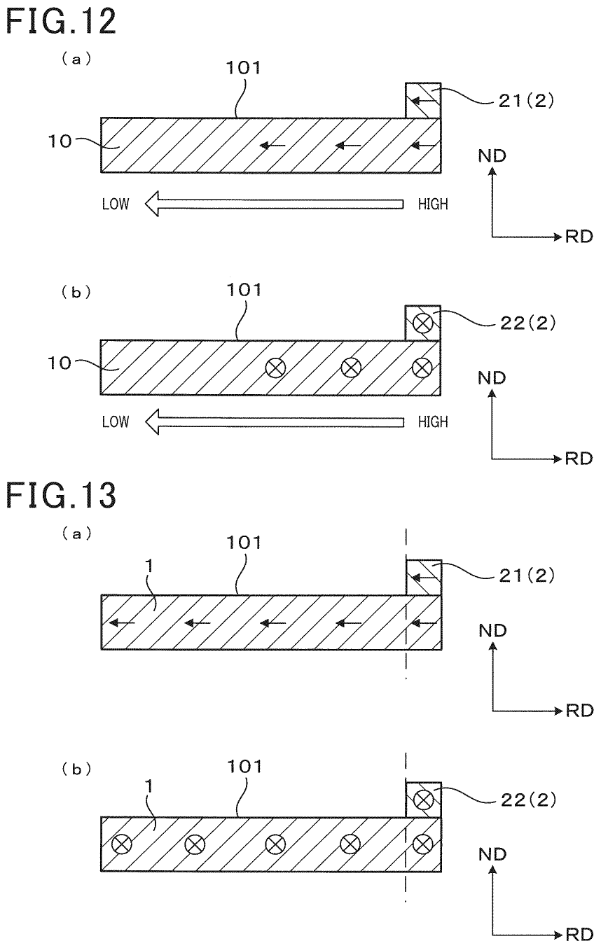

Subsequently, as shown in FIGS. 12 (a) and (b), heat treatment is performed in which the first single crystal steel 21, the second single crystal steel 22, and the polycrystalline steel plate 10 are heated from a contact portion side at which the single crystal steels 2 are in contact with the polycrystalline steel plate 10. By the heat treatment, in the polycrystalline steel plate 10, crystal growth in the thickness direction ND occurs following crystal orientations of the first single crystal steel 21 and the second single crystal steel 22. Furthermore, following crystal orientations of crystals grown in the polycrystalline steel plate 10, crystal growth proceeds in the direction perpendicular to the thickness direction ND. Specifically, as shown in FIGS. 12 (a) and (b), crystal growth proceeds, for example, in the rolling direction RD.

In the heat treatment, it is preferable to form a temperature gradient in which the contact portion side of the single crystal steels 2 with the polycrystalline steel plate 10 is at a high temperature and the temperature decreases as the distance from the contact portion side, for example, in the rolling direction RD increases. In this case, crystal growth at a portion distant from the contact portion can be prevented, and crystal growth in the entire polycrystalline steel plate 10 in the rolling direction RD can be achieved in which first, crystal growth following the crystal orientations of the single crystal steels 2 occurs at a portion immediately below the contact portion, and subsequently, crystal growth occurs in the direction away from the contact portion in the rolling direction RD. For example, the temperature gradient can be formed by performing heat treatment in an inclined furnace. Other than the inclined furnace, the temperature gradient can be formed, for example, by local heating using a laser, induction heating, or the like. Hollow arrows in FIG. 12 indicate the temperature gradient, and the head of the arrows is on a low temperature side and the tail of the arrows is on a high temperature side.

Also in the present embodiment, as in the first embodiment, single crystals following the crystal orientations of the first single crystal steel 21 and the second single crystal steel 22 are grown in the polycrystalline steel plate 10, In the present embodiment, since the single crystal steels 2 are arranged at the end portion of the polycrystalline steel plate 10 in the rolling direction RD, after the heat treatment, by cutting, in the thickness direction ND, the end portion of the polycrystalline steel plate 10 in the rolling direction RD, the single crystal steels 2 can be easily removed. A cutting position is, for example, a position indicated by a dashed line in FIGS. 13 (a) and (b). After the end portion of the polycrystalline steel plate 10 in the rolling direction RD is cut in the thickness direction ND, by further performing cutting, polishing, and the like so that surfaces of the single crystal steels 2 are exposed, reusable single crystal steels 2 can be obtained.

In general, the polycrystalline steel plate 10 is supplied as a roll taken up in the rolling direction RD. By arranging the single crystal steels 2 in contact with the end portion of the polycrystalline steel plate 10 in the rolling direction RD while the polycrystalline steel plate 10 is drawn from the roll of the polycrystalline steel plate 10, the steps for manufacturing the oriented steel plate 1, such as the contact arrangement, heat treatment, and cutting can be continuously performed. Thus, the arrangement of the single crystal steels 2 at the end portion of the polycrystalline steel plate 10 in the rolling direction RD improves productivity of the manufacture of the oriented steel plate 1. The rest of the configuration of the present embodiment is the same as that of the first embodiment, and the present embodiment exhibits the same effects as those of the first embodiment.

(Second Modification)

A second modification is an example in which three or more single crystal steels 2 are used to manufacture the oriented steel plate 1. Except that three or more single crystal steel are used, the oriented steel plate 1 is manufactured in the same manner as the second embodiment.

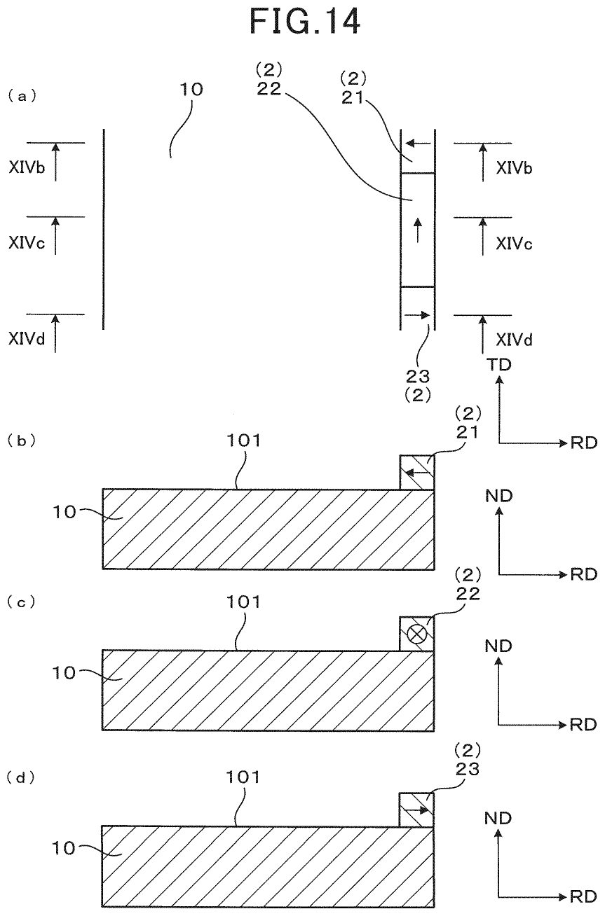

As shown in FIG. 14 (a) to (d), the three or more single crystal steels 21, 22, and 23 are arranged in contact with the principal surface 101 of the polycrystalline steel plate 10. In the second modification, as in the second embodiment, the single crystal steels 2 are arranged in contact with the end portion of the polycrystalline steel plate 10, for example, in the rolling direction RD. The single crystal steels 2 are arranged, for example, in series on the principal surface 101 of the polycrystalline steel plate 10.

FIG. 14 (a) to (d) show the three single crystal steels, which are the first single crystal steel 21, the second single crystal steel 22, and the third single crystal steel 23, arranged at the end portion of the polycrystalline steel plate 10 in the rolling direction RD, but two or more other single crystal steels 2 may be arranged in series in the transverse direction TD. Subsequently, by performing heat treatment, for example, in the inclined furnace in the same manner as the second embodiment, crystal growth following crystal orientations of the single crystal steels 2 proceeds in the polycrystalline steel plate 10. This makes it possible to obtain the oriented steel plate 1 having three or more oriented regions each of which has a desired crystal orientation.

### Experimental Example 1

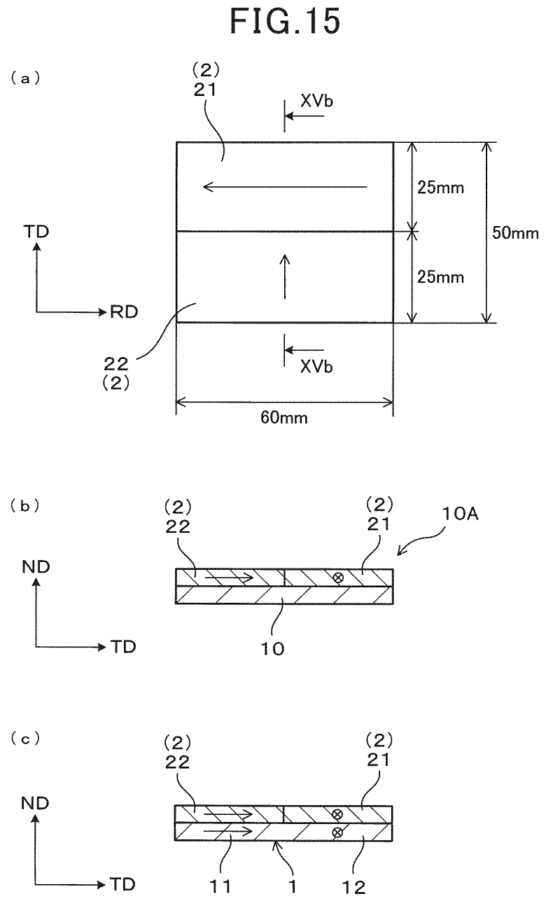

In Experimental Example 1, with reference to FIGS. 15 to 19, an example will be described in which the oriented steel plate 1 is manufactured and a crystal orientation of the manufactured oriented steel plate 1 is examined. First, the first single crystal steel 21, the second single crystal steel 22, and the polycrystalline steel plate 10 were prepared. The polycrystalline steel plate 10 was a ferritic steel plate. The polycrystalline steel plate 10 had a polycrystalline structure including many crystal grains having different crystal orientations. The first single crystal steel 21 and the second single crystal steel 22 were a ferritic steel plate. The first single crystal steel 21 and the second single crystal steel 22 were a single crystal.

Specifically, as the polycrystalline steel plate 10, a non-oriented electromagnetic steel plate containing 2.5 wt % of Si was used. The polycrystalline steel plate 10 had a length L of 1000 mm in the rolling direction RD, a width B of 300 mm in the transverse direction TD, and a thickness t of 0.8 mm. As the single crystal steel 2, an oriented electromagnetic steel plate containing 3 wt % of Si was used. The oriented electromagnetic steel plate was composed of a single crystal steel having a specific crystal orientation. The oriented electromagnetic steel plate had a length L of 1000 mm in the rolling direction RD, a width B of 300 mm in the transverse direction TD, and a thickness t of 0.23 mm.

The polycrystalline steel plate 10 was subjected to rolling at a rolling reduction ratio of 12.5% so that the polycrystalline steel plate 10 had a final thickness t of 0.7 mm. Subsequently, the polycrystalline steel plate 10 was cut to have a length L of 60 mm in the rolling direction RD and a width B of 50 mm in the transverse direction TD. Furthermore, the plate-shaped single crystal steel was cut to obtain the first single crystal steel 21 having a length L of 60 mm in the rolling direction RD and a width B of 25 mm in the transverse direction TD and the second single crystal steel 22 having a length L of 25 mm in the rolling direction RD and a width B of 60 mm in the transverse direction TD.

Next, surfaces of the polycrystalline steel plate 10, the first single crystal steel 21, and the second single crystal steel 22 obtained by the cutting were polished to remove an oxide film and cause a surface roughness Ra to be less than 3.2 μm. Subsequently, as shown in FIGS. 15 (a) and (b), the first single crystal steel 21 and the second single crystal steel 22 were arranged in contact with the principal surface 101 of the polycrystalline steel plate 10. At this time, the first single crystal steel 21 and the second single crystal steel 22 were arranged on the polycrystalline steel plate 10 so that a crystal orientation of the first single crystal steel 21 was perpendicular to a crystal orientation of the second single crystal steel 22.

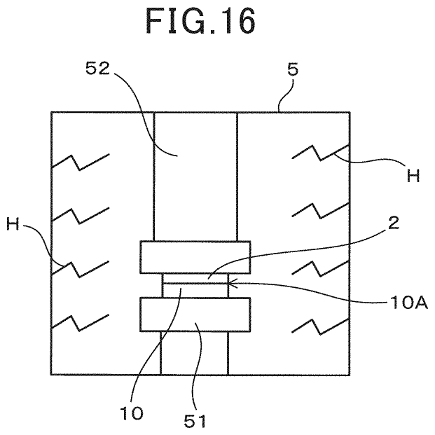

Next, the polycrystalline steel plate 10 with which the first single crystal steel 21 and the second single crystal steel 22 were in contact was subjected to heat treatment. Hereinafter, the polycrystalline steel plate 10 with which the first single crystal steel 21 and the second single crystal steel 22 are in contact is referred to as a material 10A to be treated. As shown in FIG. 16, the heat treatment was performed in a heating furnace 5. As the heating furnace 5, a resistance heating vacuum hot pressing furnace manufactured by Fuji Electric Co., Ltd. was used. The heating furnace 5 included a base 51, a pressurizing press 52, a heater embedded in a furnace wall, an exhaust port for hot air H provided on a wall surface, and the like. In FIG. 16, the heater and the exhaust port are omitted.

The heat treatment was performed in the following manner. First, the material 10A to be treated was placed on the base 51. Next, a degree of vacuum in the heating furnace 5 was set to 10⁻³ Pa or less. Subsequently, while the pressurizing press 52 was operated to apply pressure at 600 N to the material 10A to be treated in the thickness direction ND, a temperature was increased at 6° C./min to 1100° C. and maintained for 2 hours. Then, the material 10A to be treated was naturally cooled for approximately 8 hours. Thus, as shown in FIG. 15 (c), the oriented steel plate 1 having the at least two oriented regions 11 and 12 having different crystal orientations was obtained.

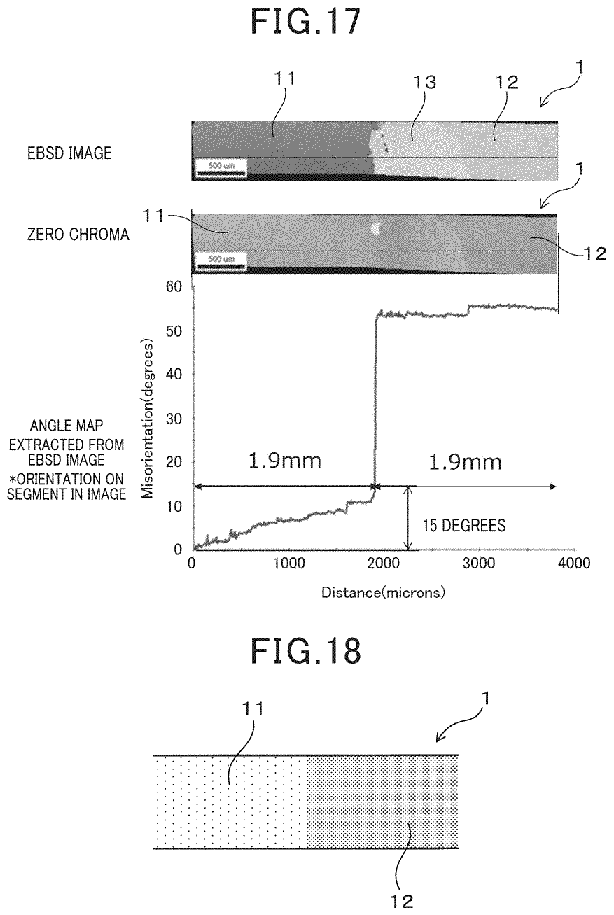

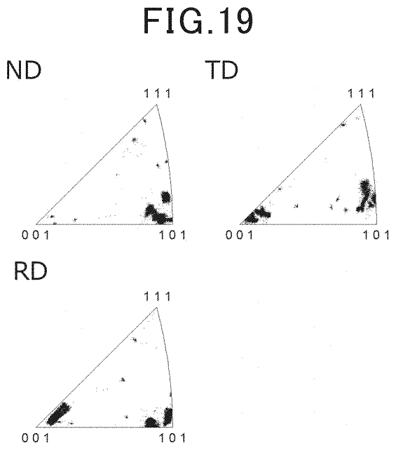

Next, a crystal orientation of the oriented steel plate 1 was examined. The crystal orientation was measured by the EBSD method using, as a measurement device, JSM-7100F manufactured by JEOL Ltd. The crystal orientation was measured under conditions where a measurement magnification was 100 times, a step size was 1 μm, a frame rate was 140 fps, and an irradiation voltage was 15 kV. FIGS. 17 and 19 show the measurement results. FIG. 17 shows an EBSD image, an EBSD image with a chroma of zero, and an angle map extracted from the EBSD image. In the angle map in FIG. 17, a horizontal axis represents a distance, and a vertical axis represents an orientation difference (i.e., misorientation). FIG. 19 shows an inverse pole figure. While the EBSD image in FIG. 17 is a color image, FIG. 18 is a schematic diagram showing simplified arrangement of the oriented regions 11 and 12 in the EBSD image.

As shown in FIG. 18, the oriented steel plate 1 had the first oriented region 11 and the second oriented region 12, and the oriented regions 11 and 12 were each composed of a single crystal. A boundary was present between the two oriented regions 11 and 12. A portion around the boundary had a region 13 having a crystal orientation different from the crystal orientation of the first oriented region 11 and the crystal orientation of the second oriented region 12 (see FIGS. 17 and 19). The region 13 further had a plurality of regions having different crystal orientations, and each of the regions constituted a crystal grain.

As understood from the angle map in FIG. 17, a crystal orientation difference between the region 12 and the region 13 was approximately 2°, and the region 12 and the region 13 were considered to have substantially the same orientation. Thus, it was found that in the oriented steel plate 1, crystal growth occurred following the two types of crystal orientations of the first single crystal steel 21 and the second single crystal steel 22.

As understood from the inverse pole figure of the EBSD image in FIG. 19, in the oriented steel plate 1, the arrangement was concentrated in the forms <001> and <101>. This result matched the EBSD image and showed that the first oriented region 11 was arranged in the form <001> and the second oriented region 12 was arranged in the form <101>.

Thus, it was found that Experimental Example 1 can provide the oriented steel plate 1 having the two or more oriented regions 11 and 12 having different crystal orientations. The present invention is not limited to the above embodiments, but is applicable to various embodiments without departing from the gist of the present invention. For example, in Experimental Example 1, the oriented steel plate was manufactured in which the first oriented region 11 was arranged in the form <001> and the second oriented region 12 was arranged in the form <101>. However, by changing the crystal orientations of the single crystal steels, an oriented steel plate having different crystal orientations can be manufactured.

What is claimed is:

1. A method of manufacturing an oriented steel plate, the method comprising:
bringing at least two single crystal steels into contact with a principal surface of a polycrystalline steel plate, crystal orientations of the single crystal steels being arranged in different directions; and
performing heat treatment of the single crystal steels and the polycrystalline steel plate, thereby causing crystal growth following the crystal orientations of the single crystal steels to occur in the polycrystalline steel plate to form two or more single crystal steels having different crystal orientations in the polycrystalline steel plate.

2. The method of manufacturing an oriented steel plate according to claim 1, wherein before the heat treatment, the polycrystalline steel plate is provided with distortion.

3. The method of manufacturing an oriented steel plate according to claim 1, wherein the heat treatment is performed while pressure is applied to the single crystal steels and the polycrystalline steel plate in a contact direction of the single crystal steels and the polycrystalline steel plate.

4. The method of manufacturing an oriented steel plate according to claim 1, wherein the heat treatment is performed while the single crystal steels are in surface contact with the polycrystalline steel plate.

5. The method of manufacturing an oriented steel plate according to claim 1, wherein:
the single crystal steels have a plate shape; and
the heat treatment is performed while principal surfaces of the single crystal steels are in contact with the principal surface of the polycrystalline steel plate.

6. The method of manufacturing an oriented steel plate according to claim 1, wherein a heating temperature of the heat treatment is in the range of 500° C. or more and 1500° C. or less.

7. The method of manufacturing an oriented steel plate according to claim 1, wherein the single crystal steels are brought into contact with an end portion of the principal surface of the polycrystalline steel plate, and in the heat treatment, a temperature gradient is formed in which a temperature decreases as a distance from the end portion increases.
